(19) United States
(12) Patent Application Publication
(10) Pub. No.: US 2026/0181798 A1
(43) Pub. Date: Jun. 25, 2026

(54) DISPLAY DEVICE AND VEHICLE

(71) Applicant: LG Display Co., Ltd., Seoul (KR)

(72) Inventor: Sangho JANG, Daegu (KR)

(73) Assignee: LG Display Co., Ltd., Seoul (KR)

(21) Appl. No.: 19/403,452

(22) Filed: Nov. 28, 2025

(30) Foreign Application Priority Data
Dec. 19, 2024 (KR) 10-2024-0190898

(51) Int. Cl. H05K 5/02; H05K 5/03; H10K 59/80

(52) U.S. Cl. CPC H05K 5/0217; H05K 5/03; H10K 59/873

(57) ABSTRACT

A display device and a vehicle including the display device are discussed. In the display device, a display panel that has a cover member disposed thereon and displays an image on a front surface thereof is seated on a set frame. When the display panel is driven in a display mode, the display panel in an apron area is bent and a coupling fastening portion of the cover member is coupled and fastened to an apron fastening portion. Therefore, when the display panel is bent and the cover member is slid during the driving in the display mode, the cover member is fastened and fixed to the set frame, thereby preventing or minimizing the cover member from being lifted.

### CROSS REFERENCE TO RELATED APPLICATION

Pursuant to 35 U.S.C. § 119(a), this application claims the benefit of an earlier filing date and right of priority to Korean Patent Application No. 10-2024-0190898, filed on December 19, 2024 in the Korean Intellectual Property Office, the contents of which are incorporated by reference herein in their entirety.

### BACKGROUND

### Technical Field

The present disclosure relates to a display device, and more particularly, for example, without limitation, to a display device mounted in a vehicle and the vehicle.

### Discussion of the Related Art

As the use of a display device is being diversified, a range of use thereof is becoming wider as a thickness thereof is decreased and a weight thereof is decreased. A demand for a display device that provides a high-quality image is increasing as the display device is used in various fields.

Recently, a vehicle display device in which the display device is disposed inside a vehicle such that an image is provided to a user sitting in a driver's seat or a passenger seat has been disseminated.

The vehicle display device includes a display area (also referred to as an active area or AA)) that displays a screen and a non-display area (also referred to as a non-active area or NA) formed along an outer portion of the display area. The non-display area is also called a bezel area.

The description provided in the background section should not be assumed to be prior art merely because it is mentioned in or associated with the background section. The background section can include information that describes one or more aspects of the subject technology.

### SUMMARY OF THE DISCLOSURE

Among the display panels of vehicle display devices, an auto plastic OLED (PO) model has a structure in which the display panel is bent for image display, and can have a problem in that buckling and lifting of a cover member (e.g., cover Glass or CG) can occur by stress caused by the bending of the display panel.

To solve or address the above-described problems and other limitations associated with the related art, the inventor of the present application has invented an improved display device that prevents or minimizes the buckling and the lifting of the cover member CG from occurring when the display panel is bent.

A purpose of the present disclosure is to provide a display device that can prevent or minimize the buckling and the lifting of the cover member CG by fastening and fixing the cover member to a set frame when the cover member is slid as the display panel is bent during driving in an image display mode.

Purposes according to the present disclosure are not limited to the above-mentioned purposes. Other purposes and advantages according to the present disclosure that are not mentioned can be understood based on following descriptions, and can be more clearly understood based on example implementations according to the present disclosure. Further, it will be easily understood that the purposes and advantages according to the present disclosure can be realized using means shown in the claims or combinations thereof.

In the display device according to example implementations of the present disclosure, a display panel that has a cover member disposed thereon and displays an image on a front surface thereof is seated on a set frame, and when the display panel is driven in a display mode, the display panel in an apron area is bent and a coupling fastening portion of the cover member is coupled and fastened to an apron fastening portion.

Details of other example implementations of the present disclosure are included in the detailed description and drawings.

Solutions for the problems and limitations associated with the related art according to the example implementations of the present disclosure are not limited to the above-mentioned or below-mentioned solutions, and other solutions not mentioned will be clearly understood by those skilled in the art from the following description.

The display device according to the example implementations of the present disclosure can prevent or minimize the lifting phenomenon of the cover member by fastening and fixing the cover member to the set frame when the cover member is slid as the display panel is bent during the driving in the display mode.

In addition, the display device according to the example implementations of the present disclosure can reduce the buckling defects by offsetting the reaction force of the cover member when the cover member is slid as the display panel is bent during the driving in the display mode.

In addition, the display device according to the example implementations of the present disclosure can prevent or minimize the cover member from being pushed and detached by fastening and fixing the same to the apron frame when the cover member is slid.

In addition, the display device according to the example implementations of the present disclosure can prevent or minimize an occurrence of a screen abnormality or a crack in the display panel by preventing or minimizing the cover member from being pushed or lifted during the driving in the image display mode.

In addition, according to the example implementations of the present disclosure, the occurrence of the pushing or the lifting of the cover member can be prevented or minimized, and the occurrence of the crack of the display panel can be prevented or minimized, thereby improving the lifespan of the display device and implementing the long-life display device.

In addition, according to the example implementations of the present disclosure, the quality of the display device can be improved by preventing or minimizing the occurrence of the defect when the display device mounted in the vehicle is driven in the image display mode.

In addition, according to the example implementations of the present disclosure, production energy can be reduced by preventing or minimizing the occurrence of the defect in the display device.

In addition, according to the example implementations of the present disclosure, as the quality of the display device is improved, reliability can be secured accordingly, thereby implementing a narrow bezel.

The effects of the present disclosure are not limited to the above-mentioned effects, and other effects not mentioned can be clearly understood by those skilled in the art from the following descriptions.

In addition to the above-described effects, the specific effects of the present disclosure will be described together while describing specific matters for implementing the example implementations of the present disclosure below.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a display device according to an example implementation of the present disclosure.

FIG. 2 is a diagram illustrating a set frame including an apron area according to an example implementation of the present disclosure.

FIG. 3 is a view illustrating a rear surface of a display panel according to an example implementation of the present disclosure.

FIG. 4 is a cross-sectional view illustrating a cross-section taken along a line A-A' in FIG. 1 of a display device according to an example implementation of the present disclosure.

FIG. 5 is an enlarged perspective view of a portion B in FIG. 4 in a display device according to an example implementation of the present disclosure.

FIG. 6 is a perspective view illustrating a configuration example of a cover member according to an example implementation of the present disclosure.

FIG. 7 is a perspective view illustrating an example of a structure when an apron area according to an example implementation of the present disclosure is in a flat mode.

FIG. 8 is a cross-sectional view illustrating a cross-section taken along a line C-C' in FIG. 7 in an apron area according to an example implementation of the present disclosure.

FIG. 9 is a diagram illustrating a state of a connector when an apron area according to an example implementation of the present disclosure is in a flat mode.

FIG. 10 is a view illustrating a bent state when an apron area according to an example implementation of the present disclosure is in a sliding mode.

FIG. 11 is a diagram illustrating a state of a display panel when an apron area according to an example implementation of the present disclosure is in a sliding mode.

FIG. 12 is a perspective view illustrating a fastened state when an apron area according to an example implementation of the present disclosure is in a sliding mode.

FIG. 13 is a diagram illustrating a state of a connector in a sliding mode on an apron area according to an example implementation of the present disclosure.

FIG. 14 is a diagram illustrating an example of a fastening structure of an apron fastening portion according another example implementation of the present disclosure.

FIG. 15 is a diagram illustrating an example of a fastening structure of an apron fastening portion according to another example implementation of the present disclosure.

FIG. 16 is a diagram illustrating an example of a fastening structure of an apron fastening portion according to another example implementation of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION S OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and Advantages and features of the present disclosure, and a method of achieving the advantages and features will become apparent with reference to example implementations described later in detail together with the accompanying drawings. However, the present disclosure is not limited to the example implementations as disclosed under, but can be implemented in various different forms. Thus, these example implementations are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various example implementations are illustrated and described further below. It will be understood that the description herein is not intended to limit the claims to the specific example implementations described. On the contrary, it is intended to cover alternatives, modifications, and equivalents as can be included within the spirit and scope of the present disclosure as defined by the appended claims.

A shape (e.g., sizes, lengths, widths, heights, thicknesses, locations, radii, diameters, and areas), a ratio, an angle, a number, etc. disclosed in the drawings for illustrating example implementations of the present disclosure are illustrative, and the present disclosure is not limited thereto. Any implementation described herein as an “example” is not necessarily to be construed as preferred or advantageous over other implementations.

The word “exemplary” is used to mean serving as an example or illustration. Aspects are example aspects. The terms such as “embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise. Further, the term “can” encompasses all the meanings of the term “may” and vice versa.

The terminology used herein is directed to the purpose of describing particular example implementations only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this disclosure, specify the presence of the stated features, integers, operations, elements, and/or components, but do not preclude the presence or addition of one or more other features, integers, operations, elements, components, and/or portions thereof. As used herein, the term "and/or" includes any and all combinations of one or more of associated listed items. Expression such as "at least one of" when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present "on" a second element or layer, the first element can be disposed directly on the second element or can be disposed indirectly on the second element with a third element or layer being disposed between the first and second elements or layers. It will be understood that when an element or layer is referred to as being "connected to", or "coupled to" another element or layer, it can be directly connected to, or coupled to the other element or layer, or one or more intervening elements or layers can be present therebetween. In addition, it will also be understood that when an element or layer is referred to as being "between" two elements or layers, it can be the only element or layer between the two elements or layers, or one or more intervening elements or layers can also be present.

Further, as used herein, when a layer, film, area, plate, or the like is disposed "on," “above”, “over,” "on top," etc. of another layer, film, area, plate, or the like, the former can directly contact the latter or still one or more other layers, films, areas, plates, or the like can be disposed between the former and the latter. As used herein, in one example, when a layer, film, area, plate, or the like is directly disposed "on" or "on top" of another layer, film, area, plate, or the like, the former directly contacts the latter and still another layer, film, area, plate, or the like is not disposed between the former and the latter. Further, as used herein, when a layer, film, area, plate, or the like is disposed "beneath," “under,” “below,” etc. another layer, film, area, plate, or the like, the former can directly contact the latter or still one or more other layers, films, areas, plates, or the like can be disposed between the former and the latter. As used herein, in one example, when a layer, film, area, plate, or the like is directly disposed "beneath" or "under" another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

When a certain implementation can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms such as "first", "second", "third", “A,” “B,” “(a),” and “(b)” and so on can be used herein to describe various elements, components, areas, layers and/or periods, these elements, components, areas, layers and/or periods should not be limited by these terms. These terms are used to distinguish one element, component, area, layer or section from another element, component, area, layer or period, and may not define order or sequence. Thus, a first element, component, area, layer or section as described under could be termed a second element, component, area, layer or period, without departing from the spirit and scope of the present disclosure.

When an example implementation can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The features of the various example implementations of the present disclosure can be partially or entirely combined with each other, and can be technically associated with each other or operate with each other. The example implementations can be implemented independently of each other and can be implemented together in an association relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “example implementations,” “exemplary implementations,” “examples,” “aspects, and the like should not be construed such that any aspect or design as described is superior to or advantageous over other aspects or designs.

Further, the term 'or' means 'inclusive or' rather than 'exclusive or'. That is, unless otherwise stated or clear from the context, the expression that 'x uses a or b' means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating example implementations.

Further, in a specific case, a term can be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B through another node unless a phrase 'immediately transferred' or 'directly transferred' is used.

Throughout the present disclosure, "A and/or B" means A, B, or A and B, unless otherwise specified, and "C to D" means C inclusive to D inclusive unless otherwise specified.

Further, the phrase such as “at least one” should be understood to include any combination of one or more of listed components. For example, at least one of first, second, and third components means not only a first, second, or third component, but also all combinations of two or more of the first, second, and third components.

As used herein, the term "display device" can include, in a narrow sense, a display device including a liquid crystal module (LCM), an organic light-emitting diode (OLED) module, or a quantum dot (QD) module including a display panel and a driver for driving the display panel, without being limited thereto. Moreover, the display device can include, in a broad sense, a laptop computer, a television, a computer monitor, an automotive device or an equipment display for a vehicle, a set electronic device, a set device or a set device including a complete product or a final product including the LCM, the OLED module, or the QD module, without being limited thereto.

Therefore, the display device in accordance with the present disclosure can include, in the narrow sense, a display device itself including, for example, the LCM, the OLED module, QD module, etc., and can include, in a broad sense, the set device as an application product or an end-user device including a complete product or a final product including the LCM, the OLED module, or the QD module.

Moreover, in some cases, the LCM, OLED module, or QD module composed of the display panel and the driver can be expressed as "display device" in a narrow sense. The electronic device as a complete product including the LCM, OLED module or QD module can be expressed as "set" device" in a broad sense. For example, the display device in the narrow sense can include a display panel such as a liquid crystal panel, an organic light-emitting display panel, or a quantum dot display panel, and a source PCB as a controller for driving the display panel. The set device in the broad sense can include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel can be of any type of the display panels such as a liquid crystal display panel, an organic light emitting diode (OLED) display panel, a quantum dot (QD) display panel, and an electroluminescent display panel, etc. The display panel used in the disclosure may not be limited to a specific display panel including a flexible substrate for the OLED display panel and an underlying back plate support structure and having a bendable bezel. Moreover, the display panel used in the display device according to an example implementation of the present disclosure is not limited to a shape or a size of the display panel.

Hereinafter, example implementations of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure can work functionally.

Hereinafter, a display device and a vehicle according to example implementations of the present disclosure will be described with reference to the drawings. All the components of each display device/apparatus and each vehicle or other medium including the display device/apparatus are operatively coupled and configured.

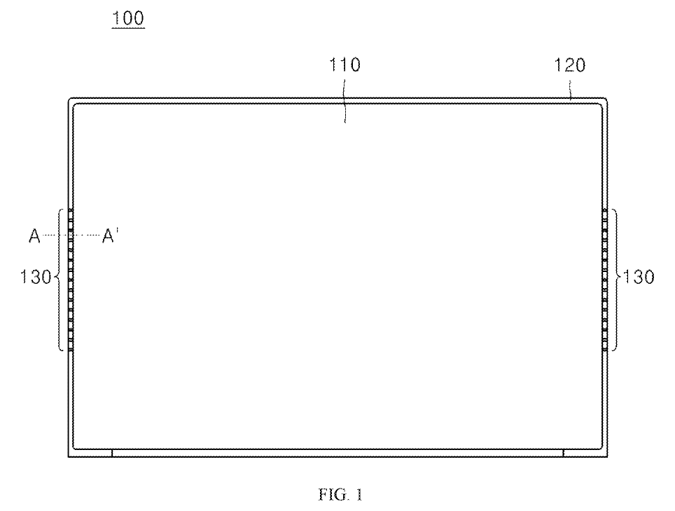

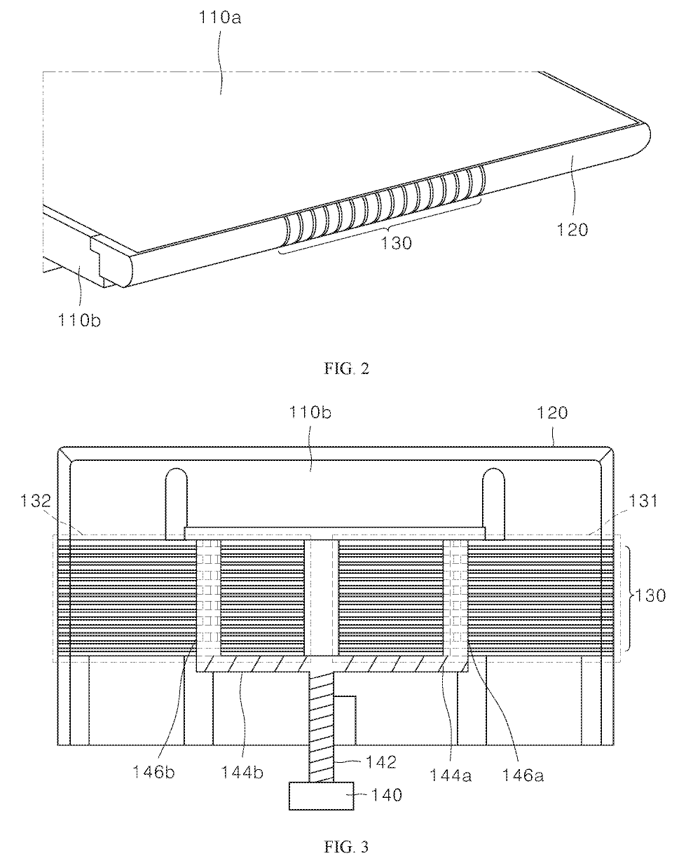

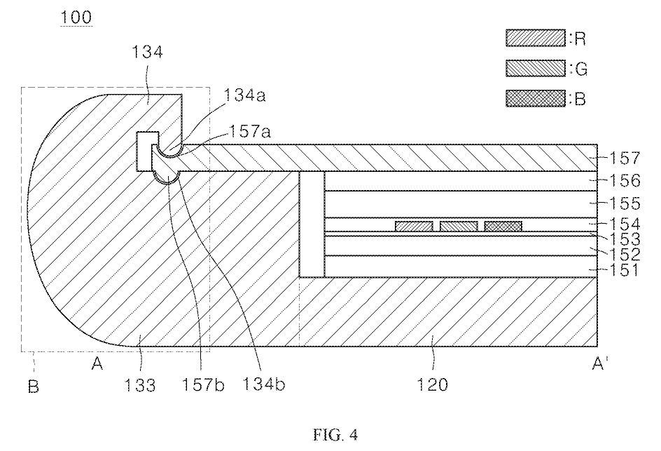

FIG. 1 is a plan view illustrating a display device according to an example implementation of the present disclosure. FIG. 2 is a diagram illustrating a set frame including an apron area according to an example implementation of the present disclosure. FIG. 3 is a view illustrating a rear surface of a display panel according to an example implementation of the present disclosure. FIG. 4 is a cross-sectional view illustrating a cross-section taken along a line A-A' in FIG. 1 of a display device according to an example implementation of the present disclosure.

Referring to FIG. 1, a display device 100 according to an example implementation of the present disclosure can include a display panel 110 that displays an image on a front surface thereof, and a set frame 120 including an apron area 130 in which the display panel 110 is bent.

The display panel 110 is seated on the set frame 120, and the apron area 130 is disposed in a predetermined section along a periphery of the set frame 120. The apron area 130 can be an area in which the display panel 110 is bent when the display panel 110 is display-driven in a display mode.

Referring to FIG. 2, the set frame 120 can be formed in an edge shape surrounding the display panel 110 along an edge of the display panel 110 on a front surface 110a of the display panel 110.

The front surface 110a of the display panel 110 can be disposed on top of the set frame 120 and a rear surface 110b of the display panel 110 can be disposed beneath the set frame 120, and the apron area 130 can be disposed in a center area along the edge, without being limited thereto.

Referring to FIGS. 1 and 3, the apron area 130 can be located at a central portion between both ends of a short side among a long side and the short side of the display panel 110 on the front surface 110a of the display panel 110. Embodiments are not limited thereto. As an example, the apron area 130 can be located at any position on the long side or the short side of the display panel 110 on the front surface 110a of the display panel 110, without being limited thereto. As an example, the apron area 130 can be biased from the central portion of the short side of the display panel 110. As an example, the apron area 130 can be located at a central portion between both ends of a long side of the display panel 110 on the front surface 110a of the display panel 110, without being limited thereto. As an example, the apron area 130 can be located at the same portion or different portions on both short sides or both long sides of the display panel 110, without being limited thereto.

Referring to FIG. 3, the apron area 130 can include a first apron portion 131 and a second apron portion 132, which are disposed at a central portion in a vertical direction on the rear surface 110b of the display panel 110.

As an example, the first apron portion 131 and the second apron portion 132 can be disposed to be spaced apart from each other on both sides with respect to a central virtual line in a left and right direction, without being limited thereto. As an example, the first apron portion 131 and the second apron portion 132 can be disposed to be spaced apart from each other at an equal spacing on both sides with respect to the central virtual line in a left and right direction, without being limited thereto.

The first apron portion 131 can be disposed on a left side with respect to the central virtual line on the rear surface 110b of the display panel 110, and the second apron portion 132 can be disposed on a right side with respect to the central virtual line on the rear surface 110b of the display panel 110.

In addition, as an example, a rotation driver 140, a rotation screw 142, a first power transmitter 144a, a second power transmitter 144b, a first connector 146a, and a second connector 146b can be disposed on the rear surface 110b of the display panel 110 illustrated in FIG. 3, without being limited thereto. As an example, at least one of the above-mentioned components can be omitted, or at least one additional component can be further included.

The rotation driver 140 generates a rotational force.

The rotation screw 142 rotates based on the rotational force generated by the rotation driver 140.

The first power transmitter 144a is in association with the rotation screw 142 and transmits the rotational force to the first apron portion 131 as power.

The second power transmitter 144b is in association with the rotation screw 142 and transmits the rotational force to the second apron portion 132 as power.

The power transmitted from the first power transmitter 144a and the second power transmitter 144b to the first and second apron portions 131 and 132, respectively, includes power required for a linear motion and power for bending.

The first connector 146a connects the first power transmitter 144a with the first apron portion 131. Accordingly, the first apron portion 131 bends the display panel 110 based on the power transmitted from the first power transmitter 144a.

The second connector 146b connects the second power transmitter 144b with the second apron portion 132. Accordingly, the second apron portion 132 bends the display panel 110 based on the power transmitted from the second power transmitter 144b.

When the display panel 110 is display-driven, the first connector 146a and the second connector 146b bend the display panel 110 and the set frame 120 corresponding to the apron area 130 in a direction of the rear surface 110b of the display panel 110 based on the power received from the first power transmitter 144a and the second power transmitter 144b.

A cover member (TCG) 157 can be disposed on top of the display panel 110. The cover member 157 can include a cover window and a cover glass, without being limited thereto. For example, the cover member 157 can be a thin cover glass (TCG) that is thin with a thickness equal to or smaller than a predetermined value.

The cover member 157 can be disposed to cover the front surface of the display panel 110 and protect the display panel 110 from an external impact. An edge of the cover member 157 can have a rounded shape formed to be curved in a rearward direction in which the display panel 110 is disposed. In this case, the cover member 157 can be disposed to cover at least a partial area of a side surface of the display panel 110 disposed on a rear surface thereof, and thus, can serve to protect not only the front surface of the display panel 110 but also the side surface thereof from the external impact. As an example, the edge of the cover member 157 can extend beyond the display panel 110 in a lateral direction, without being limited thereto. As an example, the edge of the cover member 157 extending beyond the display panel 110 in the lateral direction can have the rounded shape. As an example, the rounded shape of the edge of the cover member 157 can overlap the display panel 110 in the lateral direction.

Such a cover member 157 can be, for example, made of any one of poly methyl methacrylate (PMMA), poly carbonate (PC), cycloolefin polymer (COP), polyethylene terephthalate (PET), polyimide (PI), and polyaramid (PA) having impact resistance and light transmittance. Example implementations of the present disclosure are not limited thereto.

Because the cover member 157 includes a display area AA that displays a screen, it can be made of a transparent material such as the cover glass so as to display the screen. For example, the cover member 157 can be made of a transparent plastic material, a glass material, or a reinforced glass material., without being limited thereto

Referring to FIG. 4, the cover member 157 can have a coupling fastening portion 157a and 157b formed at a distal end thereof, and an apron fastening portion 134 can be formed at the apron area 130.

Accordingly, when the display panel 110 is display-driven, the coupling fastening portion 157a and 157b of the cover member 157 and the apron fastening portion 134 can be coupled and fastened with each other.

Referring to FIG. 4, the display device 100 can further include an apron frame 133 formed to extend from the set frame 120 in an outward direction.

The apron frame 133 and the set frame 120 can be stepped from each other, and the apron fastening portion 134 and the cover member 157 can be disposed on an upper portion of the apron frame 133. As an example, the apron frame 133 can be stepped from the set frame 120 in a direction of the display panel (e.g., a forward direction), such that the apron frame 133 can overlap a side surface of the display panel 110 in the lateral direction. As an example, the set frame 120, the apron frame 133 and the cover member 157 can surround an edge of the display panel 110, without being limited thereto.

As an example, the apron fastening portion 134 can include a fastening protrusion 134a and a fastening groove 134b, without being limited thereto.

As an example, the fastening protrusion 134a can extend upward from a top surface of the apron frame 133, be bent in a lateral direction, and then be bent in a downward direction to be convex, without being limited thereto.

The fastening groove 134b can be formed in a concave shape in the top surface of the apron frame 133 corresponding to the fastening protrusion 134a.

The cover member 157 can have the coupling fastening portion 157a and 157b formed at the distal end thereof. The coupling fastening portion 157a and 157b can correspond to the apron fastening portion 134.

The coupling fastening portion 157a and 157b can include a coupling groove 157a and a coupling protrusion 157b. The coupling groove 157a and the coupling protrusion 157b can be smoothly coupled and fastened with each other and fixed by applying, for example, a urethane heterojunction structure, without being limited thereto.

The coupling groove 157a can be concavely formed at a distal end of a top surface of the cover member 157 corresponding to the fastening protrusion 134a of the apron fastening portion 134.

The coupling protrusion 157b can be convexly formed at a distal end of a bottom surface of the cover member 157 corresponding to the fastening groove 134b.

In FIG. 4, in the display device 100, a top surface of the set frame 120 formed to be stepped from the apron frame 133 can be formed lower than a top surface of the apron frame 133.

In addition, as an example, the display device 100 can include a plate bottom 151, a back plate 152, an adhesive layer 153, a panel substrate 154, a polarizing layer (POL) 155, an optical adhesive layer (OCA) 156, and the cover member 157. Embodiments are not limited thereto. As an example, at least one of the above-mentioned components can be omitted, or at least one additional component can be further included.

For example, in the display device 100, the plate bottom 151 can be disposed on the top surface of the set frame 120, the back plate 152 can be disposed on the plate bottom 151, the adhesive layer 153 can be disposed on the back plate 152, the panel substrate 154 can be disposed on the adhesive layer 153, the polarizing layer 155 can be disposed on the panel substrate 154, the optical adhesive layer 156 can be disposed on the polarizing layer 155, and the cover member 157 can be disposed on the optical adhesive layer 156.

The panel substrate 154 can include a plurality of sub-pixels. Each of the sub-pixels can include a light emitting element. For example, the display device 100 according to the example implementations of the present disclosure can be an organic light emitting display device in which the light emitting element is implemented as an organic light emitting diode (OLED). As another example, the display device 100 according to the example implementation of the present disclosure can be an inorganic light emitting display device in which the light emitting element is implemented as an inorganic material-based light emitting diode. As another example, the display device 100 according to the example implementation of the present disclosure can be a quantum dot display device in which the light emitting element is implemented as a quantum dot, which is a semiconductor crystal emits light by itself. But the present disclosure is not limited thereto.

A structure of each of the multiple sub-pixels can vary depending on a type of the display device 100. For example, when the display device 100 is a self-light emitting display device in which the sub-pixel emits light by itself, each sub-pixel can include a light emitting element that emits light by itself, one or more transistors, and one or more capacitors.

For example, various types of signal lines can include multiple data lines that transmit data signals (also referred to as data voltages or image signals), multiple gate lines that transmitting gate signals (also referred to as scan signals), and the like.

The multiple data lines and the multiple gate lines GL can cross each other. Each of the multiple data lines can extend in a first direction. Each of the multiple gate lines can extend in a second direction. Here, the first direction can be a column direction, and the second direction can be a row direction. The first direction can be the row direction, and the second direction can be the column direction. But the present disclosure is not limited thereto.

On the panel substrate 154, the multiple sub-pixels can be arranged in a matrix form, each sub-pixel can be composed of sub-pixels of different colors, for example, a red sub-pixel R, a green sub-pixel G, and a blue sub-pixel B, and each sub-pixel can be defined by the multiple data lines and the multiple gate lines. Embodiments are not limited thereto. As an example, sub pixels of other colors such as white, cyan, magenta, or yellow, etc. can be alternatively or additionally included.

The polarizing layer 155 reduce or prevents a decrease in contrast ratio (CR) caused by external light. In the display device 100 according to the present disclosure, an OLED panel improves the contrast ratio by positioning the polarizing layer 155 that blocks external light incident from the outside in a transmission direction of light emitted through the display panel in a driven mode of implementing an image. The polarizing layer 155 is not an essential component in the example implementation of the present specification, and may not be included. The example implementations of the present disclosure are not limited thereto.

The optical adhesive layer 156 can include an optical clear adhesive (OCA). The optical adhesive layer 156 can have a thickness in a range of, for example, 100 to 300㎛. When the optical adhesive layer 156 has a thickness equal to or smaller than 100㎛, an adhesive strength is weakened, so that it can be difficult to modularize the cover member 157, the plate bottom 151, and the back plate 152. Further, when the optical adhesive layer 156 has a thickness equal to or greater than 300㎛e, folding in the display device 100 can become difficult. Accordingly, the optical adhesive layer 156 can have the thickness in the range of 100 to 300㎛.

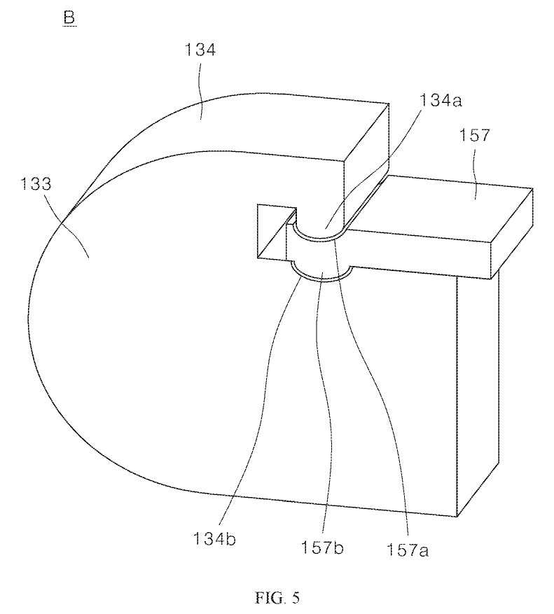

FIG. 5 is an enlarged perspective view of a portion B in FIG. 4 in a display device according to an example implementation of the present disclosure.

Referring to FIG. 5, in the display device 100 according to the example implementation of the present disclosure, the portion B in FIG. 4 shows an example of a configuration of the apron frame 133, and is an enlarged perspective view showing the state in which the coupling fastening portion 157a and 157b of the cover member 157 is coupled and fastened to the apron fastening portion 134.

The apron fastening portion 134 can be formed at the upper portion of the apron frame 133. The apron fastening portion 134 can include the fastening protrusion 134a protruding downward from the upper portion of the apron frame 133, and the fastening groove 134b concavely formed in a stepped surface corresponding to the fastening protrusion 134a.

The coupling fastening portion 157a and 157b of the cover member 157 fastened to the apron fastening portion 134 can be disposed on the stepped surface at the upper portion of the apron frame 133.

The coupling fastening portion 157a and 157b of the cover member 157 can include the coupling groove 157a concavely formed in the top surface of the cover member 157 and the coupling protrusion 157b protruding from the bottom surface of the cover member 157.

In this regard, the apron fastening portion 134 and the coupling fastening portion 157a and 157b of the cover member 157 can be coupled and fastened with each other as follows. They can be coupled and fastened with each other as the fastening protrusion 134a of the apron fastening portion 134 is inserted into the coupling groove 157a of the cover member 157 and the coupling protrusion 157b of the cover member 157 is inserted into the fastening groove 134b of the apron fastening portion 134.

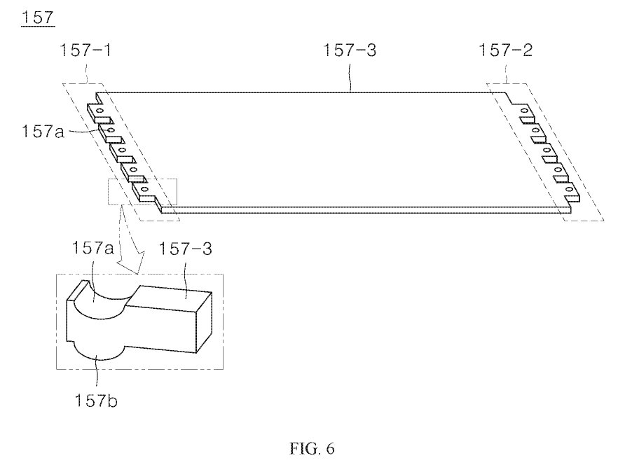

FIG. 6 is a perspective view illustrating a configuration example of a cover member according to an example implementation of the present disclosure.

Referring to FIG. 6, the cover member 157 according to the example implementation of the present disclosure can include a body 157-3, a first fastening portion 157-1, and a second fastening portion 157-2.

The body 157-3 can be formed in, for example, the urethane heterojunction coupling structure.

The first fastening portion 157-1 can include multiple first fastening portions formed at one end (a left end) extending from the body 157-3 outward toward one side (e.g., a left side).

The second fastening portion 157-2 can include multiple second fastening portions formed at the other end (a right end) extending from the body 157-3 outward toward the other side (e.g., a right side).

As an example, one first fastening portion 157-1 can include a coupling groove 157a and a coupling protrusion 157b, without being limited thereto. As an example, one first fastening portion 157-1 can include two or more coupling grooves 157a and two or more coupling protrusions 157b. As an example, the number of the coupling grooves 157a and the number of coupling protrusions 157b can be the same as or different from each other. As an example, the coupling grooves 157a and the coupling protrusions 157b can overlap each other in the vertical direction, without being limited thereto.

The coupling groove 157a can be concavely formed in a top surface of the one end (the left end) extending from the body 157-3 outward toward the one side (e.g., the left side).

The coupling protrusion 157b can correspond to the coupling groove 157a, and can be formed to convexly protrude from a bottom surface of the one end (the left end) extending from the body 157-3 outward toward the one side (e.g., the left side).

One second fastening portion 157-2 can include the coupling groove 157a and the coupling protrusion 157b in the same manner as the first fastening portion 157-1, but have a difference only in a direction.

The coupling groove 157a can be concavely formed in a top surface of the other end (the right end) extending from the body 157-3 outward toward the other side (the right side).

The coupling protrusion 157b can correspond to the coupling groove 157a, and can be formed to convexly protrude from a bottom surface of the other end (the right end) extending from the body 157-3 outward toward the other side (the right side).

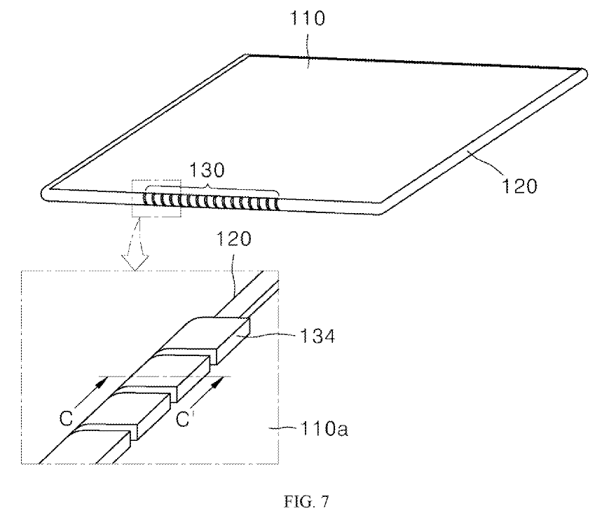

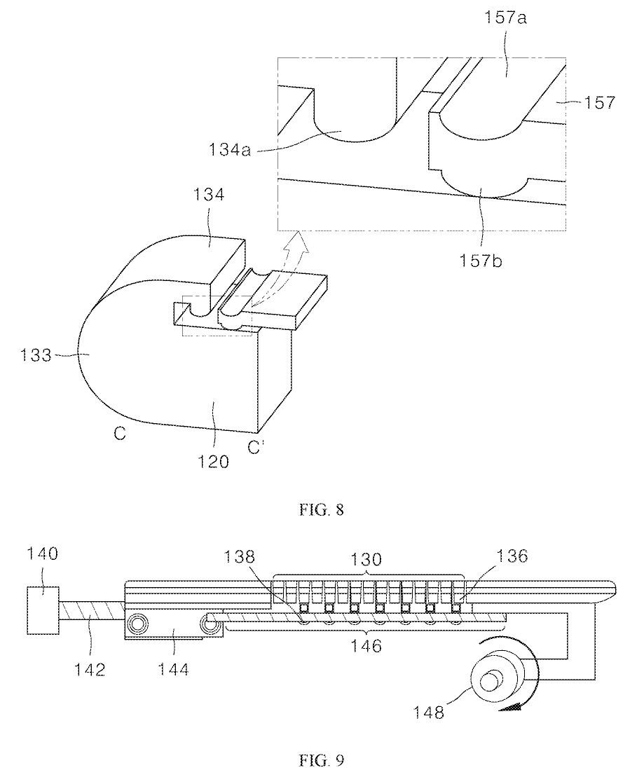

FIG. 7 is a perspective view illustrating an example of a structure when an apron area according to an example implementation of the present disclosure is in a flat mode. FIG. 8 is a cross-sectional view illustrating a cross-section taken along a line C-C' in FIG. 7 in an apron area according to an example implementation of the present disclosure. FIG. 9 is a diagram illustrating a state of a connector when an apron area according to an example implementation of the present disclosure is in a flat mode.

Referring to FIG. 7, the apron area 130 according to the example implementation of the present disclosure can be in the flat mode in a flat state when the display panel 110 is driven in a non-display mode.

In the flat mode, when the display device 100 according to the example implementation of the present disclosure is applied to a vehicle, for example, the display panel 110 can be in a state of being inserted into a dashboard of the vehicle, without being limited thereto. Accordingly, the flat mode can be an image non-display driven mode of the display panel 110.

In the flat mode, the apron fastening portion 134 is in a state of being spaced apart from the coupling fastening portion 157a and 157b of the cover member 157.

Referring to FIG. 8, the coupling fastening portion 157a and 157b of the cover member 157 can be spaced apart from the apron fastening portion 134 at a predetermined spacing without being fastened to the apron fastening portion 134 while the display panel 110 is driven in a non-display mode. As an example, the coupling fastening portion 157a and 157b of the cover member 157 can be spaced apart from the apron fastening portion 134 at a predetermined spacing in the lateral direction while the display panel 110 is driven in a non-display mode, without being limited thereto. As an example, the coupling fastening portion 157a and 157b of the cover member 157 can be closer to the display panel 110 than the apron fastening portion 134 while the display panel 110 is driven in a non-display mode, without being limited thereto.

Referring to FIG. 9, on the apron area 130, when the display panel 110 is driven in a non-display mode, the display panel 110 and the connector 146 corresponding to the apron area 130 can be maintained in the flat state. The connector 146 includes the first connector 146a and the second connector 146b.

As an example, the connector 146 does not receive any power from the power transmitter 144 to which the rotational force is not transmitted from the rotation driver 140 through the rotation screw 142, so that the display panel 110 and the connector 146 are maintained in the flat state.

As an example, each of the first connector 146a and the second connector 146b can include multiple apron bars 136 having the same length as the long side of the display panel 110, without being limited thereto.

Accordingly, when the display panel 110 is driven in a display mode, the multiple apron bars 136 of the first connector 146a and the second connector 146b can be moved toward a separation space between the first connector 146a and the second connector 146b by a predetermined distance.

Accordingly, the apron fastening portion 134 and the coupling fastening portion 157a and 157b of the cover member 157 can be coupled and fastened to each other based on the movement of the multiple apron bars 136 of the first connector 146a and the second connector 146b by the predetermined distance.

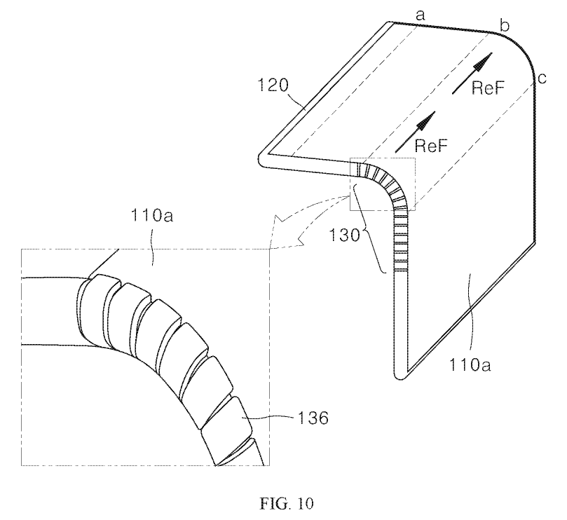

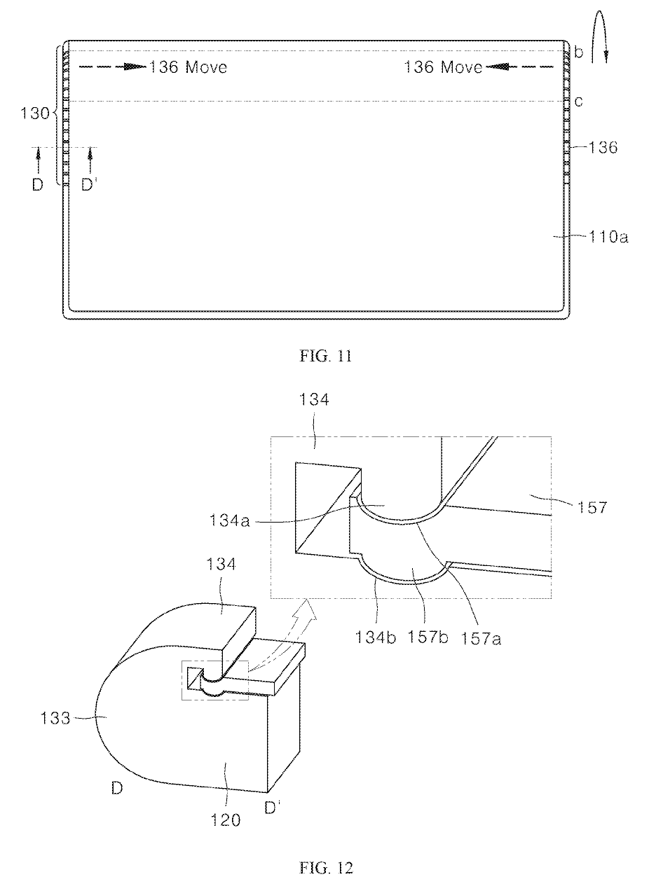

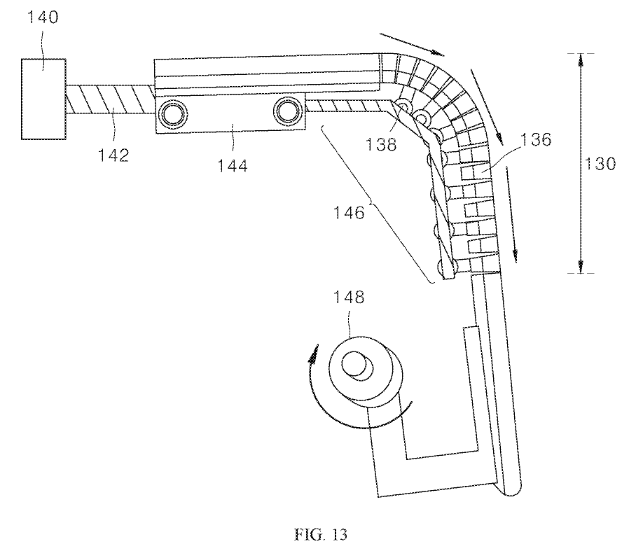

FIG. 10 is a view illustrating a bent state when an apron area according to an example implementation of the present disclosure is in a sliding mode. FIG. 11 is a diagram illustrating a state of a display panel when an apron area according to an example implementation of the present disclosure is in a sliding mode. FIG. 12 is a perspective view illustrating a fastened state when an apron area according to an example implementation of the present disclosure is in a sliding mode. FIG. 13 is a diagram illustrating a state of a connector in a sliding mode on an apron area according to an example implementation of the present disclosure.

The sliding mode can be, for example, a state in which the display panel 110 protrudes from the dashboard of the vehicle when the display device 100 according to the example implementation of the present disclosure is applied to the vehicle. Accordingly, the sliding mode can be the image display driven mode of the display panel 110.

Referring to FIGS. 10 to 13, on the apron area 130, when the display panel 110 is driven in a display mode, the first connector 146a and the second connector 146b corresponding to the apron area 130 bend the display panel 110 and the set frame 120 corresponding to the apron area 130 in a direction of the rear surface 110b of the display panel 110 based on the power transmitted from the first power transmitter 144a and the second power transmitter 144b.

At this time, in the front surface 110a of the display panel 110, a section a to b is in the flat state, and a section b to c corresponding to the apron area 130 is bent.

Accordingly, the apron area 130 generates a reaction force ReF in response to bending stress as shown in FIG. 10.

Therefore, in the apron area 130, the apron bars 136 move slightly toward a center by the reaction force caused by the bending, and accordingly, as shown in FIG. 12, the apron fastening portion 134 is coupled and fastened to the coupling fastening portion 157a and 157b of the cover member 157.

At this time, as illustrated in FIG. 13, on the apron area 130, the connector 146 receives the rotational force transmitted from the rotation driver 140 through the rotation screw 142 and converted as linear power by the power transmitter 144 and transmits the linear power to a roll rotator 148, thereby bending the display panel 110 and the set frame 120 and sliding the apron bars 136. Accordingly, as the apron bars 136 slide, the apron fastening portion 134 is coupled and fastened to the coupling fastening portion 157a and 157b of the cover member 157.

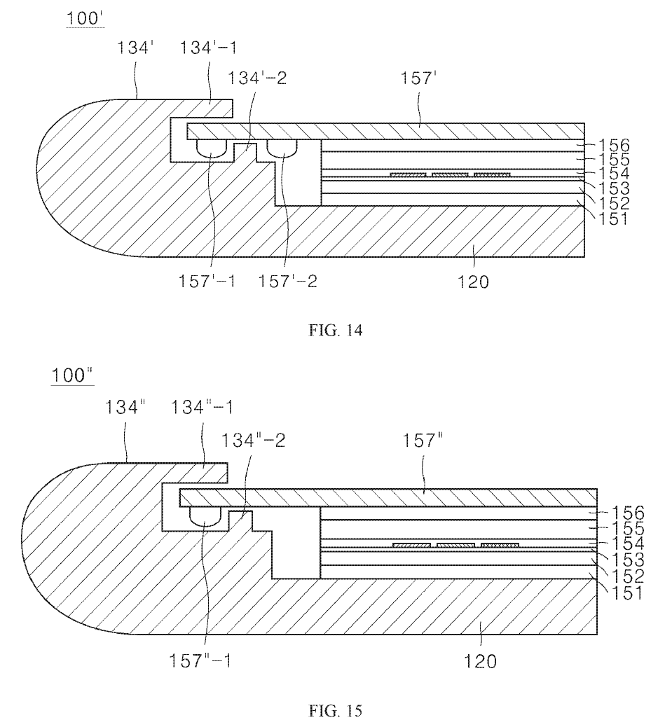

FIG. 14 is a diagram illustrating an example of a fastening structure of an apron fastening portion according to another example implementation of the present disclosure.

Referring to FIG. 14, an apron fastening portion 134' according to the example implementation of the present disclosure can include a protruding portion 134'-1 protruding from the upper portion of the apron frame 133 to cover a distal end of the cover member 157'; and a locking jaw 134'-2 for fixing the distal end of the cover member 157' located below the protruding portion 134'-1.

In this regard, the cover member 157' can include a first protrusion 157'-1 protruding downward from a bottom surface of the distal end positioned below the protruding portion 134'-1; and a second protrusion 157'-2 spaced apart from the first protrusion 157'-1 at a predetermined spacing and protruding downward from a bottom surface of the cover member 157'.

Accordingly, the apron fastening portion 134' can be coupled and fastened to the cover member 157' such that the locking jaw 134'-2 is positioned between the first protrusion 157'-1 and the second protrusion 157'-2.

FIG. 15 is a diagram illustrating an example of a fastening structure of an apron fastening portion according to another example implementation of the present disclosure.

Referring to FIG. 15, an apron fastening portion 134" according to the example implementation of the present disclosure can include a protruding portion 134"-1 protruding from the upper portion of the apron frame 133 to cover a distal end of a cover member 157"; and a locking jaw 134"-2 for fixing the distal end of the cover member 157" located below the protruding portion 134"-1.

In this regard, the cover member 157'' can include a protrusion 157''-1 protruding downward from a bottom surface of the distal end positioned below the protruding portion 134''-1.

Accordingly, the apron fastening portion 134'' can be coupled and fastened to the cover member 157'' such that the protrusion 157''-1 formed at the distal end of the cover member 157'' is inserted into a space under the protruding portion 134''-1 and caught by the locking jaw 134''-2.

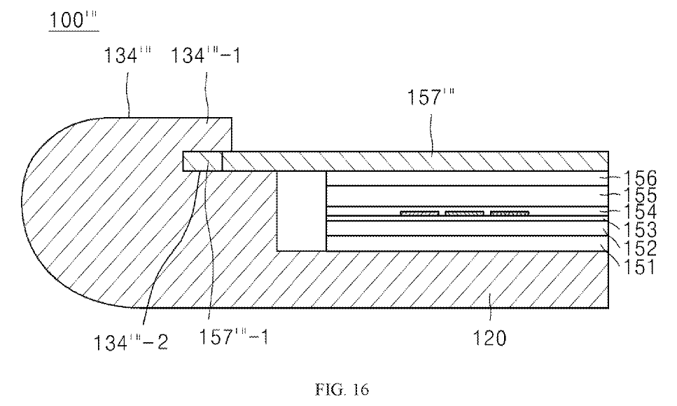

FIG. 16 is a diagram illustrating an example of a fastening structure of an apron fastening portion according to another example implementation of the present disclosure.

Referring to FIG. 16, an apron fastening portion 134’” according to the example implementation of the present disclosure can include a protruding portion 134’”-1 protruding from the upper portion of the apron frame 133 to cover a distal end of a cover member 157’”.

In this regard, an insertion hole 134’”-2 can be defined between a surface formed at the upper portion of the apron frame 133 stepped from the set frame 120 and the protruding portion 134’”-1.

As an example, a height of the insertion hole 134’”-2 can be the same as or smaller than a thickness of the cover member 157’”, without being limited thereto. As an example, a height of the insertion hole 134’”-2 can be the same as or smaller than a thickness of the distal end of the cover member 157’”, without being limited thereto. As an example, the distal end of the cover member 157’” can have a thickness greater than, equal to or smaller than the remaining portion of the cover member 157’”, without being limited thereto.

The apron fastening portion 134’” can be coupled and fastened to the cover member 157’” as a distal end 157’”-1 of the cover member 157’” is inserted into the insertion hole 134’”-2. As an example, the insertion hole 134’”-2 can have a length equal to or longer than the distal end 157’”-1 of the cover member 157’”, such that a space or no space can be presented between the insertion hole 134’”-2 and the distal end 157’”-1 even when the distal end 157’”-1 of the cover member 157’” is inserted into the insertion hole 134’”-2, without being limited thereto.

As described above, according to the example implementation of the present disclosure, a display device that reduce or prevents buckling and lifting of the cover member CG from occurring when the display panel is bent can be realized.

As an example, according to the example implementations of the present disclosure, a display device that can reduce or prevent the buckling and the lifting of the cover member CG by fastening and fixing the cover member to the set frame when the display panel is bent and the cover member is slid during the driving in the image display mode can be provided.

The display device according to the example implementations of the present disclosure can be described as follows.

A display device according to an example implementation of the present disclosure includes a display panel 110 that has a cover member (TCG) 157 disposed thereon and displays an image on a front surface thereof, and a set frame 120 where the display panel is seated and including an apron area 130 bendable when the display panel is driven in a display mode, a coupling fastening portion 157a and 157b is formed at a distal end of the cover member 157, an apron fastening portion 134 is formed at the apron area, and the coupling fastening portion and the apron fastening portion are coupled and fastened to each other when the display panel is driven in the display mode.

According to some example implementations of the present disclosure, the set frame can be formed in an edge shape surrounding the display panel along an edge of the display panel on the front surface 110a of the display panel.

According to some example implementations of the present disclosure, the apron area 130 can be located at a central portion between both ends of a short side among a long side and the short side of the display panel on the front surface 110a of the display panel.

According to some example implementations of the present disclosure, the apron area 130 can include a first apron portion 131 and a second apron portion 132 disposed at a central portion in a vertical direction on a rear surface 110b of the display panel, wherein the first apron portion 131 and the second apron portion 132 can be disposed to be spaced apart from each other at a predetermined spacing on both sides with respect to a central virtual line in a left and right direction.

According to some example implementations of the present disclosure, on the rear surface 110b of the display panel, a rotation driver 140 that generates a rotational force, a rotation screw 142 that rotates based on the rotational force generated by the rotation driver, a first power transmitter 144a that transmits the rotational force to the first apron portion as power in association with the rotation screw, a second power transmitter 144b that transmits the rotational force to the second apron portion as power in association with the rotation screw, a first connector 146a connecting the first power transmitter with the first apron portion, and a second connector 146b connecting the second power transmitter with the second apron portion are disposed.

According to some example implementations of the present disclosure, the first connector and the second connector can bend the display panel and the set frame corresponding to the apron area in a rearward direction of the display panel based on the power respectively received from the first power transmitter and the second power transmitter when the display panel is driven in the display mode.

According to some example implementations of the present disclosure, the display device can further include an apron frame 133 extending from the set frame in an outward direction, the apron frame can be formed to be stepped from the set frame, and the apron fastening portion 134 and the cover member can be disposed on an upper portion of the apron frame.

According to some example implementations of the present disclosure, the apron fastening portion can include a fastening protrusion 134a extending upward from a top surface of the apron frame, bent in a lateral direction, and then bent in a downward direction to be convex, and a fastening groove 134b formed in a concave shape in the top surface of the apron frame corresponding to the fastening protrusion.

According to some example implementations of the present disclosure, the cover member can include the coupling fastening portion formed at the distal end thereof and corresponding to the apron fastening portion, and the coupling fastening portion can include a coupling groove 157a concavely defined at a distal end of a top surface thereof corresponding to the fastening protrusion of the apron fastening portion, and a coupling protrusion 157b convexly formed at a distal end of a bottom surface thereof corresponding to the coupling groove.

According to some example implementations of the present disclosure, a top surface of the set frame formed to be stepped from the apron frame can be formed to be lower than the top surface of the apron frame, and a plate bottom 151 can be disposed on the top surface of the apron frame, a back plate 152 can be disposed on the plate bottom, an adhesive layer 153 can be disposed on the back plate, a panel substrate 154 can be disposed on the adhesive layer, a polarizing layer 155 can be disposed on the panel substrate, an optical adhesive layer 156 can be disposed on the polarizing layer, and a cover member 157 can be disposed on the optical adhesive layer.

According to some example implementations of the present disclosure, the cover member 157 can include a body 157-3, multiple first fastening portions 157-1 formed at one end extending from the body outward toward one side, and multiple second fastening portions 157-2 formed at an end opposite to the one end extending from the body outward toward a side opposite to the one side.

According to some example implementations of the present disclosure, one of the multiple first fastening portions can include a coupling groove 157a concavely defined in a top surface of the one end extending from the body outward toward the one side, and a coupling protrusion 157b corresponding to the coupling groove and convexly protruding from a bottom surface of the one end extending from the body outward toward the one side.

According to some example implementations of the present disclosure, one of the multiple second fastening portions can include a coupling groove 157a concavely defined in a top surface of the end opposite to the one end extending from the body outward toward the side opposite to the one side, and a coupling protrusion 157b corresponding to the coupling groove and convexly protruding from a bottom surface of the end opposite to the one end extending from the body outward toward the side opposite to the one side.

According to some example implementations of the present disclosure, the coupling fastening portion of the cover member may not be fastened to the apron fastening portion and can be spaced apart from the apron fastening portion at a predetermined spacing when the display panel is driven in a non-display mode.

According to some example implementations of the present disclosure, the display panel, the first connector, and the second connector corresponding to the apron area can be maintained in a flat state on the apron area when the display panel is driven in a non-display mode.

According to some example implementations of the present disclosure, on the apron area, when the display panel is driven in a display mode, the first connector and the second connector corresponding to the apron area can bend the display panel and the set frame corresponding to the apron area in a rearward direction of the display panel based on the power respectively received from the first power transmitter and the second power transmitter.

According to some example implementations of the present disclosure, each of the first connector and the second connector can include multiple apron bars having the same length as a long side of the display panel, when the display panel is driven in the display mode, the multiple apron bars of each of the first connector and the second connector can be moved to a separation space between the first connector and the second connector by a predetermined distance, and the apron fastening portion and the coupling fastening portion of the cover member can be fastened to each other based on the movement of the multiple apron bars of each of the first connector and the second connector by the predetermined distance.

According to some example implementations of the present disclosure, the apron fastening portion 134’ can include a protruding portion 134’-1 protruding from the upper portion of the apron frame to cover a distal end of the cover member, and a locking jaw 134’-2 for fixing the distal end of the cover member positioned below the protruding portion, the cover member 157’ can include a first protrusion 157’-1 protruding downward from a surface of the distal end thereof positioned below the protruding portion, and a second protrusion 157’-2 spaced apart from the first protrusion at a predetermined spacing and protruding downward from a bottom surface of the cover member, and the apron fastening portion 134’ can be coupled and fastened to the cover member such that the locking jaw 134’-2 is positioned between the first protrusion 157’-1 and the second protrusion 157’-2.

According to some example implementations of the present disclosure, the apron fastening portion 134” can include a protruding portion 134”-1 protruding from the upper portion of the apron frame to cover a distal end of the cover member, and a locking jaw 134”-2 for fixing the distal end of the cover member positioned below the protruding portion, the cover member 157” can include a protrusion 157”-1 protruding downward from a surface of the distal end thereof positioned below the protruding portion, and the apron fastening portion 134” can be coupled and fastened to the cover member such that the protrusion 157”-1 formed at the distal end of the cover member is inserted into a space under the protruding portion 134”-1 and caught by the locking jaw 134”-2.

According to some example implementations of the present disclosure, the apron fastening portion 134’” can include a protruding portion 134’”-1 protruding from the upper portion of the apron frame to cover a distal end of the cover member, an insertion hole 134’”-2 can be defined between the protruding portion and a surface formed at the upper portion of the apron frame to be stepped from the set frame, a height of the insertion hole can be equal to or smaller than a thickness of the cover member, and the distal end 157’”-1 of the cover member can be inserted into the insertion hole and coupled and fastened to the cover member.

The display device according to various aspects and embodiments of the present disclosure can be described as follows.

A first aspect of the present disclosure provides a display device comprising: a cover member; a display panel disposed under the cover member, and configured to display an image on a front surface thereof; and a set frame including an apron area in which the display panel is capable of being bent, wherein an apron fastening portion is formed at the apron area, and wherein a distal end of the cover member is fastened to the apron fastening portion when the display panel is bent.

In accordance with some embodiments of the first aspect of the present disclosure, the apron fastening portion includes: a protruding portion protruding from an upper portion of the apron frame to cover a distal end of the cover member; and a locking jaw configured to fix the distal end of the cover member positioned below the protruding portion, wherein the cover member includes: a first protrusion protruding downward from a bottom surface of the distal end the cover member positioned below the protruding portion; and a second protrusion spaced apart from the first protrusion at a predetermined spacing and protruding downward from a bottom surface of the cover member, and wherein the apron fastening portion is coupled and fastened to the cover member so that the locking jaw is positioned between the first protrusion and the second protrusion.

In accordance with some embodiments of the first aspect of the present disclosure, the apron fastening portion includes: a protruding portion protruding from an upper portion of the apron frame to cover a distal end of the cover member; and a locking jaw configured to fix the distal end of the cover member positioned below the protruding portion, wherein the cover member includes a protrusion protruding downward from a bottom surface of the distal end of the cover member positioned below the protruding portion, and wherein the apron fastening portion is coupled and fastened to the cover member such that the protrusion of the cover member formed at the distal end of the cover member is inserted into a space under the protruding portion and caught by the locking jaw.

In accordance with some embodiments of the first aspect of the present disclosure, the locking jaw is positioned between the display panel and the protrusion of the cover member, and the distal end of the cover member is positioned between the protruding portion of the cover member and the locking jaw.

In accordance with some embodiments of the first aspect of the present disclosure, the apron fastening portion includes a protruding portion protruding from an upper portion of the apron frame to cover a distal end of the cover member, wherein an insertion hole is defined between the protruding portion of the apron fastening portion and a surface formed at the upper portion of the apron frame stepped from the set frame, wherein a height of the insertion hole is equal to or smaller than a thickness of the distal end of the cover member, and wherein the distal end of the cover member is inserted into the insertion hole and coupled and fastened to the cover member when the display panel is bent.

In accordance with some embodiments of the first aspect of the present disclosure, the display panel is driven in a display mode when the display panel is bent.

In accordance with some embodiments of the first aspect of the present disclosure, the distal end of the cover member is spaced apart from the apron fastening portion in a lateral direction toward the display panel while the display panel is in a flat state.

A second aspect of the present disclosure provides a vehicle, comprising the display device, wherein the display panel is configured to protrude from a dashboard of the vehicle when the display panel is bent, and is configured to be inserted into the dashboard when the display panel is in a flat state.

Although some example implementations of the present disclosure have been described above with reference to the accompanying drawings, the present disclosure may not be limited to some example implementations and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some example implementations as described above are not restrictive but illustrative in all respects.

What is claimed is:

1. A display device comprising:
a cover member;
a display panel disposed under the cover member, and configured to display an image on a front surface thereof; and
a set frame including an apron area in which the display panel is capable of being bent,
wherein an apron fastening portion is formed at the apron area, and
wherein a distal end of the cover member is fastened to the apron fastening portion when the display panel is bent.

2. The display device of claim 1, wherein the set frame is formed in an edge shape surrounding the display panel along an edge of the display panel on the front surface of the display panel.

3. The display device of claim 2, wherein the apron area is located at a central portion between both ends of a short side among a long side and the short side of the display panel on the front surface of the display panel.

4. The display device of claim 1, wherein the apron area includes a first apron portion and a second apron portion disposed at a central portion in a vertical direction on a rear surface of the display panel, and
wherein the first apron portion and the second apron portion are disposed to be spaced apart from each other at a predetermined spacing on both sides with respect to a central virtual line in a left and right direction.

5. The display device of claim 4, wherein on the rear surface of the display panel, a rotation driver configured to generate a rotational force, a rotation screw configured to rotate based on the rotational force generated by the rotation driver, a first power transmitter configured to transmit the rotational force to the first apron portion as power in association with the rotation screw, a second power transmitter configured to transmit the rotational force to the second apron portion as power in association with the rotation screw, a first connector connecting the first power transmitter with the first apron portion, and a second connector connecting the second power transmitter with the second apron portion are disposed.

6. The display device of claim 5, wherein the first connector and the second connector are configured to bend the display panel and the set frame corresponding to the apron area in a rearward direction of the display panel based on the power respectively received from the first power transmitter and the second power transmitter when the display panel is driven in a display mode.

7. The display device of claim 1, further comprising an apron frame extending from the set frame in an outward direction,
wherein the apron frame is formed to be stepped from the set frame in a direction toward the display panel, and
wherein the apron fastening portion and the cover member are disposed on the apron frame.

8. The display device of claim 7, wherein the apron fastening portion includes:
a fastening protrusion extending upward from a top surface of the apron frame, bent in a lateral direction toward the display panel, and then bent in a downward direction to be convex; and
a fastening groove formed in a concave shape in the top surface of the apron frame corresponding to the fastening protrusion.

9. The display device of claim 8, wherein a coupling fastening portion is formed at the distal end of the cover member, and
wherein the coupling fastening portion and the apron fastening portion are coupled and fastened to each other when the display panel is bent.

10. The display device of claim 9, wherein the coupling fastening portion includes:
a coupling groove concavely defined at a top surface of the distal end of the cover member corresponding to the fastening protrusion of the apron fastening portion; and
a coupling protrusion convexly formed at a bottom surface of the distal end of the cover member corresponding to the fastening groove.

11. The display device of claim 10, wherein a top surface of the set frame formed to be stepped from the apron frame is formed to be lower than the top surface of the apron frame, and
wherein a plate bottom is disposed on the top surface of the set frame, a panel substrate is disposed on the plate bottom, and the cover member is disposed on the panel substrate.

12. The display device of claim 11, wherein a back plate is disposed on the plate bottom, an adhesive layer is disposed on the back plate, the panel substrate is disposed on the adhesive layer, a polarizing layer is disposed on the panel substrate, an optical adhesive layer is disposed on the polarizing layer, and the cover member is disposed on the optical adhesive layer.

13. The display device of claim 7, wherein the cover member includes:
a body;
multiple first fastening portions formed at a first end area extending from the body outward toward one side of the body; and
multiple second fastening portions formed at a second end area opposite to the first end area, the second end area extending from the body outward toward a side opposite to the one side of the body.

14. The display device of claim 13, wherein one of the multiple first fastening portions includes:
a coupling groove concavely defined in a top surface of the first end area; and
a coupling protrusion corresponding to the coupling groove and convexly protruding from a bottom surface of the first end area.

15. The display device of claim 13, wherein one of the multiple second fastening portions includes:
a coupling groove concavely defined in a top surface of the second end area; and
a coupling protrusion corresponding to the coupling groove and convexly protruding from a bottom surface of the second end area.

16. The display device of claim 10, wherein the coupling fastening portion of the cover member is not fastened to the apron fastening portion and is spaced apart from the apron fastening portion at a predetermined spacing when the display panel is maintained in a flat state.

17. The display device of claim 5, wherein the display panel, the first connector, and the second connector corresponding to the apron area are maintained in a flat state on the apron area when the display panel is maintained in a flat state.

18. The display device of claim 5, wherein on the apron area, when the display panel is bent, the first connector and the second connector corresponding to the apron area bend the display panel and the set frame corresponding to the apron area in a rearward direction of the display panel based on the power respectively received from the first power transmitter and the second power transmitter.

19. The display device of claim 18, wherein each of the first connector and the second connector includes multiple apron bars having a same length as a long side of the display panel,
wherein when the display panel is bent, the multiple apron bars of each of the first connector and the second connector are configured to move to a separation space between the first connector and the second connector by a predetermined distance, and
wherein the apron fastening portion and the distal end of the cover member are fastened to each other based on a movement of the multiple apron bars of each of the first connector and the second connector by the predetermined distance.

20. The display device of claim 19, wherein the multiple apron bars of each of the first connector and the second connector are configured to move toward the separation space between the first connector and the second connector by a reaction force associated with bending of the display panel.
